(19) United States
(12) Patent Application Publication
(10) Pub. No.: US 2009/0224500 A1
(43) Pub. Date: Sep. 10, 2009

(54) Device for determining an angle of rotation

(75) Inventors: Dirk Raschke, Auerbach/Opf. (DE); Armin Schmidbauer, Schnabelwaid (DE)

Correspondence Address: JORDAN AND HAMBURG LLP, 122 EAST 42ND STREET, SUITE 4000, NEW YORK, NY, 10168, US

(73) Assignee: ZF Friedrichshafen AG, Friedrichshafen (DE)

(21) Appl. No.: 12/378,392

(22) Filed: Feb. 13, 2009

(30) Foreign Application Priority Data
Feb. 13, 2008 (DE) DE 102008008835.8
Mar. 26, 2008 (EP) EP 08 153 328.3

(51) Int. Cl. B62D 15/02; H01L 43/06

(52) U.S. Cl. 280/93.5; 324/207.2

(57) ABSTRACT

The invention relates to a device for determining a relative angle of rotation of two components and to a torque sensor, in particular for a divided steering column with torsion bar, in which a two-stage planetary gear is provided at the division of two shaft ends. The stages of the planetary gear are distinguished by a common planet carrier; in addition, both stages have the same tooth transmission ratio. The invention furthermore relates to use in the aforesaid divided steering column with torsion bar such that the steering column or a motor vehicle is equipped with such a device for angular measurement.

### REFERENCE TO RELATED APPLICATIONS

Priority is claimed under 35 U.S.C. 119 based on DE 10 2008 008 835.3, filed Feb. 13, 2008 and EP 08 153 328.3, filed Mar. 26, 2008, the contents of which, in their entirety are hereby incorporated herein by reference.

### BACKGROUND OF THE INVENTION

The invention proceeds from a divided steering column having a torsion bar and having a torque sensor as is well-known in the prior art. In particular publications DE 10 2006 055 049 C and DE 101 52 704 A suggest such steering columns and such torque sensors.

In particular various combination sensors are known in the prior art. Thus patent DE 10 2006 055 049 C suggests a combined steering angle and torque sensor that generates two absolute angle measurement signals across an angle range of 360° on an inductive basis using eddy current damping. To this end, a steering column is divided in the normal manner by a torsion element into an input shaft and an output shaft that is flexible relative thereto. A first damping rotor is arranged at the end of the input shaft (in the vicinity of the joint), while a second damping rotor is arranged at the end of the output shaft. The divided steering column passes at a right angle through a carrier that is supplied with a plurality of flat coils in the entire 360° angle range and is fixed to the housing. The two damping rotors each carry a passive actuating element for the eddy current damping, each of which acts in a location-selective manner (i.e. without periodically repeated structures or code tracks) on the flat coils of the carrier. From the signals from the flat coils it is possible to determine the two aforesaid absolute angular measurement signals and from them the steering angle and torque can be determined (using totaling and difference).

With this technology, the redundancy that is frequently required is very simply attained using another sensor carrier (having flat coils in another measuring plane) and using the same damping rotors (having additional location-selective actuating elements in the aforesaid additional measuring plane).

### DE3738607:

A planetary gear includes a drive shaft having a sun gear, at least one planet wheel engaging in the sun gear, a fixed ring gear meshing with the planet wheel, a planet wheel carrier carrying the planet wheel, and an output shaft connected to the planet wheel carrier. The planet wheel gear and the ring gear each comprise two separate, mutually coaxial parts, one part of the ring gear being rotatable and fixable relative to the other part of the ring gear.

### DE2606724:

Delay and/or acceleration sensor for indicating exceedance of a pre-specified delay or acceleration value for a rotating part to be monitored having a flywheel that normally rotates with the rotating part to be monitored and that, when a pre-specified acceleration and/or delay value is exceeded, rotates in a limited manner relative to the rotating part, this relative rotation triggering a signal by means of a signal generating device arranged on the flywheel, a carrier device being arranged movably on the flywheel and normally rotating with the part to be monitored and the flywheel but that is rotatable relative to a controllable torque with respect to the flywheel.

### DE102005011196:

A sensor arrangement for determining a differential angle or torque is suggested having at least one sensor element that is sensitive to magnetic fields and with which the magnetic field information for a magnetic circuit can be evaluated, the magnetic circuit being rotatable relative to the sensor element in particular due to a torque acting on a torsion rod. There are flux rings that have axially running teeth that do not mesh with one another and with which the magnetic flux between the magnetic pole wheel and the sensor element can be influenced. The flux rings are embodied such that the sensor element and the magnetic pole wheel are disposed between the inner flux ring located on a smaller diameter and the outer flux ring located on a larger diameter.

### DE102005010909:

This document relates to a force and angle sensor for measuring the rotational angle of a shaft and of a force exerted on the shaft, a main printed circuit board that has a central opening through which the shaft runs and that is arranged rotation-fast relative to the housing being arranged in a housing through which the shaft runs, a first printed circuit board, for measuring the rotational angle, that is arranged rotation-fast on the shaft and that has a central opening through which the shaft runs being arranged on one side of the main printed circuit board, and a second printed circuit board, for measuring the force, that is joined rotation-fast to the shaft and that has a central opening through which the shaft runs being arranged on the other side of the main printed circuit board. The second printed circuit board is joined to the shaft rotation-fast at a second location that is spaced apart from the first location, to which location the first printed circuit board is joined rotation-fast to the shaft. Electrodes for capacitative measurement of the rotation of the first printed circuit board with respect to the main printed circuit board or for measuring the rotation of the second printed circuit board with respect to the first printed circuit board are arranged, opposing one another for measuring the angle of rotation or the force, on the mutually facing surfaces of the main printed circuit board and the first printed circuit board and on the mutually facing surfaces of the main printed circuit board and the second printed circuit board.

### DE102004027954:

Inductive angle sensor, in particular for measuring torsion angles, for instance on steering columns, having:

a stator that includes at least one exciter element and at least a first receiving element;

a first rotor;

a second rotor that includes at least one inductive coupling element and having a torsion element on which are arranged the first rotor and the second rotor, spaced apart from one another.

### DE2951148:

Measuring device for contactless static or dynamic determination of a rotational angle and/or torque on a stationary or rotating shaft, characterized by:

two bodies made of electrically conducting, non-magnetic material that are arranged coaxial to the shaft are used, of which one is joined rotation-fast to the shaft and the other is rotatable relative to the first;

a coaxial coil through which flows a high-frequency alternating current is arranged in the immediate vicinity of the two bodies;

the bodies have segments, the area of overlap of which changes as the angle of rotation between the two bodies increases, so that the relative rotation of the two bodies can be determined by measuring the changes in impedance in the coil that occur due to the eddy currents induced in the bodies.

### DE10152704:

The document relates to a motor steering system having the following elements:

having a steering wheel that is joined rotation-fast to a steering column;

having a steering pinion that meshes with a rack;

having a superimposed gearing that is connected to the steering column on the input side and to the steering pinion on the output side and that has a second input having an electric superimposed gearing

having an electronic control that is set up for controlling the electric superimposed gearing

as a function of input signals,

a servo-drive also being provided that is controlled by the electronic control and that acts on the steering pinion or on the rack.

Provided between the steering wheel and the steering pinion is a torque sensor that has a torsion rod and that supplies a torque input signal for the control. Thus steer-by-wire functions can occur without there being a reaction on the steering wheel. The superimposed gearing in the known steering column is a planetary gear having a sun gear on the steering wheel side and having planetary wheels and a star wheel on the steering pinion side. Autonomously regulated servo-interventions on the steering pinion can compensate toward the steering wheel. The planetary gear can also cause the steering to be more direct (when parking) or less direct (when driving straight ahead) for the driver. The aforesaid torque sensor is disposed at a different location and has nothing to do with the superimposed gearing.

Strain gauges and acoustic systems for determining the steering torque can also be cited as additional prior art.

### SUMMARY OF THE INVENTION

A sensor is to be provided that measures the relative angle of rotation of two half-shafts relative to one another. The preferred, but not exclusive, use of this sensor is comprised in using a torsion rod to determine the torque transmitted between the half-shafts. The angle sensor and the torque sensor should both have high resolution, work precisely, be capable of multiple turns, and be cost-effective to produce. No volute spring is used, so it is possible to attain the capability for multiple turns. The assembly space must be small, in particular it must certainly be less than 90 mm in diameter.

Provided is a mechanical planetary gear, the electrical sensors of which can be selected as desired and that works precisely and with high resolution but is still cost-effective to produce. This gear calculates, purely mechanically, the differential angle between two rotational movements and provides it to a single indicator ring. This differential movement can then be measured via the indicator ring as the temporal progression of the differential angle.

The present angle sensor and torque sensor constitute a planetary gear that can precisely determine the torque. Planetary gears have been known in the past to be used e.g. in power steering systems. The inventive two-stage planetary gear can be used wherever an angle of rotation and secondarily a torque have to be determined, e.g. in steering systems, power steering systems, electric motors, and so forth.

In the instant application, a “two-stage planetary gear” shall be construed to mean that two single-stage planetary gears are coupled via their planet carrier, which is thus a common planet carrier for the two sets of planet wheels. The first planetary gear constitutes:

a housing 3 having inner teeth that acts as a ring gear;

a first set of one or a plurality of planet wheels that are rotatably borne in a lower plane of the planet carrier; and,

a first, interiorly disposed rotor 1 having outer teeth.

The second planetary gear constitutes:

a rotation indicator having inner teeth that acts as a ring gear;

a second set of one or a plurality of planet wheels that are rotatably borne in an upper plane of the planet carrier; and,

a second, interiorly disposed rotor having outer teeth.

These two planetary gears are coupled via the common planet carrier, i.e. the lower set of planet wheels and the upper set of planet wheels can only rotate together relative to the axis of the steering column. When operating, the rotor 1 is joined rotation-fast to the lower half of the steering column, while the rotor 2 is coupled rotation-fast to the upper half of the steering column. For their part, the opposing ends of the divided steering column can be coupled via a torsion rod so that the relative rotation of the rotors 1 and 2 is the angle of rotation to be measured, which can also be converted to the desired torque using the elastic properties of the torque rod.

It should be noted that the housing, which acts as a ring gear, can be attached fixed or rotation-fast to the steering column or to the vehicle, but it does not have to be. The property of the two-stage planetary gear—to precisely indicate the differential angle—is not affected by these possible embodiments of the housing.

The ratios of the teeth can be freely selected. However, it is important that both stages of the planetary gear have the same transmission ratio.

The module of toothed wheels used can also be selected; however, it does not necessarily have to be the same in both stages.

One exemplary embodiment of the invention shall be explained using FIGS. 1 through 3.

### BRIEF DESCRIPTION OF THE DRAWINGS

FIG. 1 is an axially exploded perspective depiction of the components of the inventive device for determining a differential angle or angle of rotation;

FIG. 2 is a perspective view of the device for measuring the angle of rotation in FIG. 1 in the assembled form so that the device can be mounted at a division of two shaft stumps, e.g. of a divided steering column for a motor vehicle, which steering column is provided with a torsion rod; and

FIG. 3 depicts the inventive device for measuring the angle of rotation in FIG. 1 and FIG. 2, used as a torque sensor that is installed for instance on the steering column of a motor vehicle.

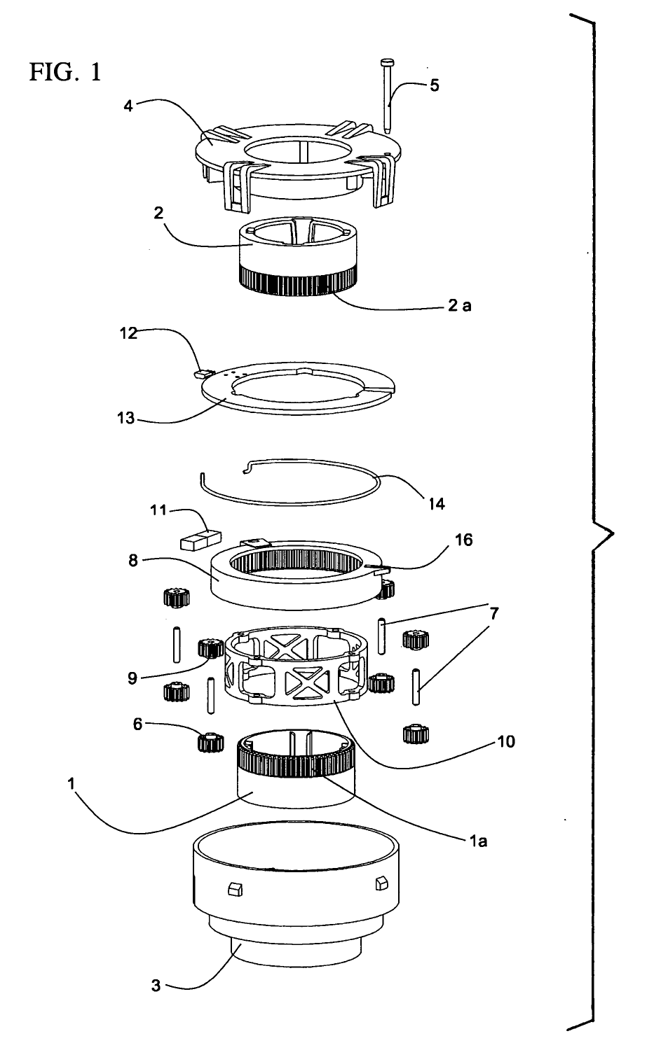

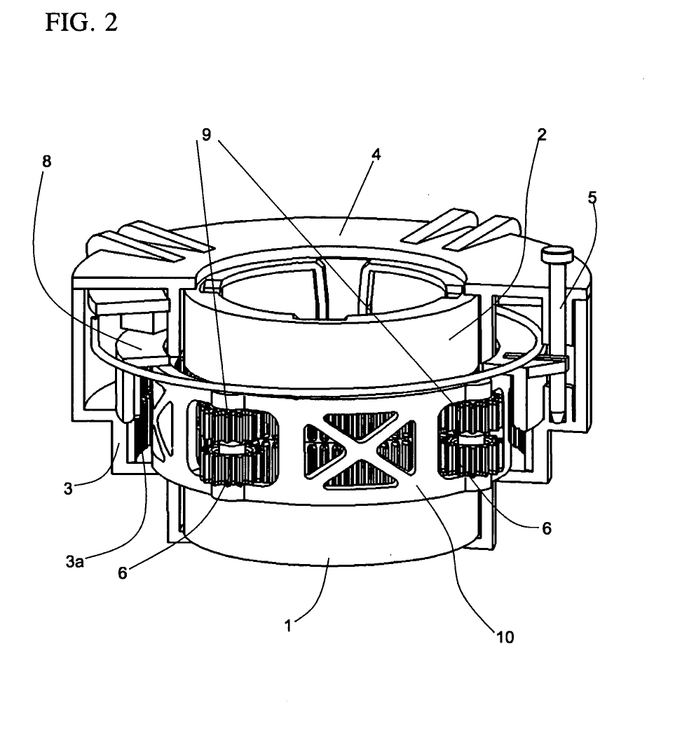

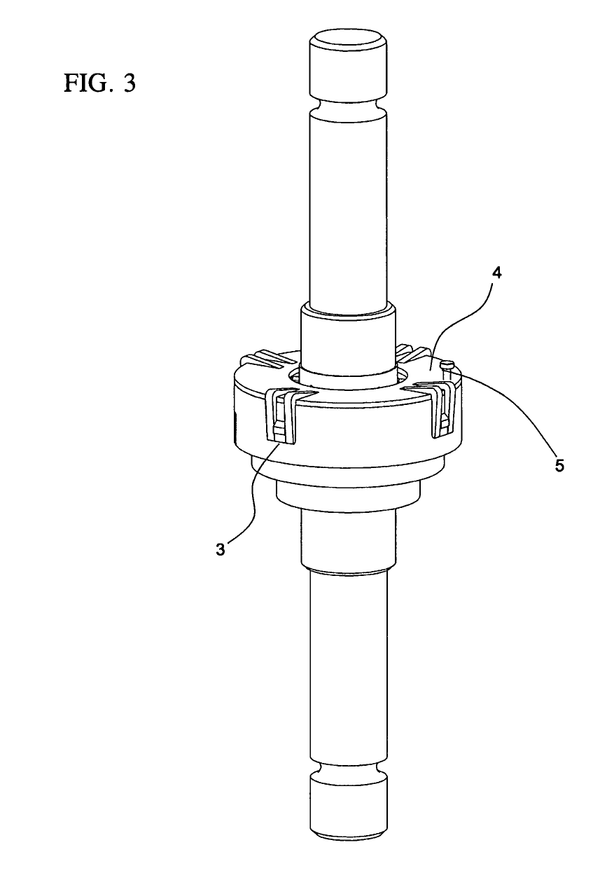

FIG. 1 and FIG. 2 depict a rotor 1 that rotates with the lower part of a steering column and a rotor 2 that rotates with the upper part of a steering column. In FIG. 2, the divided steering column should be imagined such that it passes through the torque sensor in accordance with FIG. 2 at the height of a torsion rod (not depicted). This application is explicitly depicted in FIG. 3.

A housing 3 and a housing cover 4 receive the torque sensor and protect it. The housing 3 has inner teeth 3a and thus acts as a ring gear 3, 3a for the lower planetary gear. A set of for instance four planet wheels 6 is disposed between the lower rotor 1, which has outer teeth 1a, and the ring gear 3, 3a. They rotate about planet axles 7 when the rotor 1 and the housing 3 rotate relative to one another.

The same statement and a corresponding structure apply to the upper planet stage. A rotation indicator 8 has inner teeth 8a and the upper rotor 2 has outer teeth 2a. Disposed therebetween is a set of for instance four planet wheels 9 that rotate about planet axles 7. Thus the upper rotor 2 and the rotation indicator 8 can also rotate relative to one another.

The small axles 7 are held in a planet carrier 10. The key to understanding the invention is that all of the planet wheels 6 and 9 have this planet carrier 10 in common. Thus the two stages of the planetary gear are coupled in a manner that can be visualized using the following simplified examples of an angle of rotation and torque indicator:

1. The rotor 1 is stationary; the planet carrier 10 blocks; the upper planet wheels 9 rotate due to rotation by the rotor 2; they move the rotation indicator 8; a magnet 11 on the rotation indicator 8 passes over a Hall sensor 12 that is housed on a secured printed circuit board 13.

2. In the reverse case, the rotor 2 is stationary; but now the planet carrier 10 does not block; due to a relative movement of the rotor 1, the lower planet wheels 6 roll on the ring gear 3 and move the planet carrier 10; the planet carrier 10, via the planet wheels 9 (and the stationary rotor 2), moves the rotation indicator 8; the rotation indicator 8 bears for instance the magnet 11 that passes over for instance the Hall sensor 12.

In general, neither rotor 1 nor rotor 2 is stationary, i.e. both rotors move in the use provided for. But even then their relative angle of rotation to one another is measured. The absolute angular position does not matter as long as it is only the torque transmitted in the steering column that is of interest. In each case, the angle of the rotation indicator 8 (relative to the secured printed circuit board 13, which is fixed to the housing) represents the torque sought.

This location-independence also leads to the fact that the torque can be measured within one rotation during a rotational movement of the steering column (or a comparable shaft) at any desired angular position. Rotational movements with constant moment do not change the output signal. Consequently a rotational movement without moment has no effect on the output signal, either.

Any desired sensor can be used for the actual sensor system for the differential angle, e.g. a Hall sensor, an optical sensor, an incremental encoder, an inductive sensor system, and so forth. The electrical sensor output signal is in a specific, primarily proportional relationship with the angle of rotation and torque. The torque is determined by calibration in an associated electronics system.

The measuring range for the angle of rotation, with the planetary gear, is approx. +/−25 degrees. For Hall sensors, a measuring range of +/−15 degrees makes sense because of the geometry.

Another feature of the invention is the tolerance compensation spring 14. It is used to indicate the smallest rotations by the rotors 1 and 2 reliably and rapidly. Using this spring it is also possible to use toothed wheels that have greater tolerances. Thus relatively large clearance between the individual toothed wheels can be compensated. The result is a planetary gear that works precisely and at the same time saves money despite greater production tolerances.

The pin 5 is for a locking device 16 for the two-stage planetary gear prior to mounting at the customer location. The spring 14 (tolerance and clearance compensation) exerts torque, although very slight torque, on the planetary gear. This torque could turn the planetary gear if the gear is not already secured by having been mounted on for instance a steering shaft. Mounting at the customer location would then be more complex. The locking device 16 is intended for blocking by means of the pin 5 until the device is mounted on the shaft stumps that can take torque. After mounting the pin 5 must be removed from the protected device at the user location. FIG. 3 depicts the divided steering column for a motor vehicle, on which column the inventive measuring device is mounted. From the outside it is possible to see the housing 3 and the housing cover 4. The pin 5 has not been withdrawn yet, so the locking device 16 (FIG. 1) has not been released yet. The mounting orientation can also be the reverse of FIG. 3 so that the housing 3 and the housing cover 4 are installed differently and the lower rotor 1 can be on top and the upper rotor 2 can be on top.

1-13. (canceled)

14. Apparatus for determining a relative angle of rotation of two motor vehicle parts that are rotable relative each other, comprising a two-stage planetary gear the stages of which have a same transmission ratio, each of the stages having at least one planet gear, a planet gear carrier carrying the planet gears of both stages and thereby connecting the two stages, each of the two stages further comprising a respective rotor, each of the rotors comprising a respective set of outer teeth engaging the planet gears of a respective stage and being securely joinable to a respective one of the motor vehicle parts, the apparatus further comprising a housing having inner teeth forming a first ring gear engaging the planet gears of one of stages and a rotation indicator ring having inner teeth forming a second ring gear engaging the planet gears of the other stage.

15. Apparatus according to claim 14, wherein the indicator ring is rotatably positioned within the housing.

16. Apparatus according to claim 15, further comprising a cover for the housing and wherein the indicator ring is rotatably positioned within the cover.

17. Apparatus according to claim 14, further comprising a housing cover, at least one first element of a sensor system fixedly connected to the housing or the housing cover, and at least a second element of the sensor system fixedly connected to the indicator ring whereby interaction of the first and second elements of the sensor system indicates angular position of the rotation indicator.

18. Apparatus according to claim 17, wherein the at least one first element of the sensor system comprises a circuit board with a Hall sensor connected thereto fixedly connected to the housing or the housing cover and said second element of the sensor system comprises a magnet fixedly connected to the indicator ring.

19. Apparatus according to claim 17 or 18, further comprising a tolerance compensation spring compensating tolerance of the toothing of the planetary gear by exerting slight torque on the planetary gear.

20. Apparatus according to claim 19, further comprising an insertable and removable pin engaging the housing and the housing cover when inserted thereby to prevent turning of the planetary gear.

21. A torque sensor comprising an apparatus according to any one of claims 14 to 18 and a torsion bar.

22. A divided steering column including a torque sensor according to claim 21, wherein the two motor vehicle parts that are rotatable relative to each other comprise parts into which the divided steering column is divided.

23. Motor vehicle comprising a divided steering column according to claim 22.
